(19) United States
(12) Patent Application Publication
(10) Pub. No.: US 2025/0309863 A1
(43) Pub. Date: Oct. 2, 2025

(54) MULTIPLE ELECTROMECHANICAL COUPLING COEFFICIENTS ON SAME WAFER

(71) Applicant: SKYWORKS GLOBAL PTE. LTD., Singapore (SG)

(72) Inventors: Tomoya Komatsu, Irvine, CA (US); Yiliu Wang, Irvine, CA (US); Stefan Bader, Fort Collins, CO (US); Kwang Jae Shin, Yongin-si (KR); Myung Hyun Park, Seongnam-si (KR); Martha Kennedy Small, Fort Collins, CO (US)

(21) Appl. No.: 19/085,010

(22) Filed: Mar. 20, 2025

Related U.S. Application Data
(60) Provisional application No. 63/569,859, filed on Mar. 26, 2024.
(60) Provisional application No. 63/682,890, filed on Aug. 14, 2024.

(51) Int. Cl. H03H 9/56; H03H 3/04; H03H 9/17

(52) U.S. Cl. CPC H03H 9/562; H03H 3/04; H03H 9/173; H03H 9/175; H03H 9/178; H03H 9/564; H03H 9/568; H03H 2003/0435

(57) ABSTRACT

Aspects and embodiments disclosed herein include a radio frequency filter comprising a plurality of series bulk acoustic wave resonators and a plurality of shunt bulk acoustic wave resonators, at least one of the plurality of shunt bulk acoustic wave resonators exhibiting a different electromechanical coupling coefficient than at least one of the plurality of series bulk acoustic wave resonators, at least one of the bulk acoustic wave resonators exhibiting a higher electromechanical coupling coefficient than another one of the bulk acoustic wave resonators having a thicker piezoelectric material layer stack than the another one of the bulk acoustic wave resonators.

### CROSS-REFERENCE TO RELATED APPLICATIONS

This application claims priority under 35 U.S.C. § 119(e) to U.S. Provisional Patent Application Ser. No. 63/569,859, titled “MULTIPLE ELECTROMECHANICAL COUPLING COEFFICIENTS ON SAME WAFER,” filed Mar. 26, 2024, and to U.S. Provisional Patent Application Ser. No. 63/682,890, titled “MULTIPLE ELECTROMECHANICAL COUPLING COEFFICIENTS ON SAME WAFER,” filed Aug. 14, 2024, the contents of each being incorporated herein in their entireties for all purposes.

### TECHNICAL FIELD

Embodiments of this disclosure relate to acoustic wave filters and specifically to acoustic wave filters formed with resonators having different electromechanical coupling coefficients and die including same.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a radio frequency filter. The radio frequency filter comprises a plurality of series bulk acoustic wave resonators and a plurality of shunt bulk acoustic wave resonators, at least one of the plurality of shunt bulk acoustic wave resonators exhibiting a different electromechanical coupling coefficient than at least one of the plurality of series bulk acoustic wave resonators, at least one of the bulk acoustic wave resonators exhibiting a higher electromechanical coupling coefficient than another one of the bulk acoustic wave resonators having a thicker piezoelectric material layer stack than the another one of the bulk acoustic wave resonators.

In some embodiments, the at least one of the plurality of shunt bulk acoustic wave resonators exhibits a greater electromechanical coupling coefficient than the at least one of the plurality of series bulk acoustic wave resonators.

In some embodiments, the at least one of the plurality of shunt bulk acoustic wave resonators exhibits a lesser electromechanical coupling coefficient than the at least one of the plurality of series bulk acoustic wave resonators.

In some embodiments, each of the plurality of shunt bulk acoustic wave resonators exhibits substantially the same electromechanical coupling coefficient.

In some embodiments, each of the plurality of series bulk acoustic wave resonators exhibits substantially the same electromechanical coupling coefficient.

In some embodiments, different ones of the plurality of series bulk acoustic wave resonators exhibit different electromechanical coupling coefficients.

In some embodiments, different ones of the plurality of shunt bulk acoustic wave resonators exhibit different electromechanical coupling coefficients.

In some embodiments, each of the plurality of series bulk acoustic wave resonators exhibits substantially the same electromechanical coupling coefficient.

In some embodiments, different ones of the plurality of series bulk acoustic wave resonators exhibit different electromechanical coupling coefficients.

In some embodiments, each of the plurality of series bulk acoustic wave resonators exhibits substantially the same electromechanical coupling coefficient.

In some embodiments, different ones of the plurality of series bulk acoustic wave resonators exhibit different electromechanical coupling coefficients.

In some embodiments, different ones of the plurality of series bulk acoustic wave resonators and the plurality of shunt bulk acoustic wave resonators exhibit at least three different electromechanical coupling coefficients.

In some embodiments, at least one of the plurality of shunt bulk acoustic wave resonators includes a piezoelectric material having a different impurity concentration than at least one of the plurality of series bulk acoustic wave resonators.

In some embodiments, the at least one of the plurality of shunt bulk acoustic wave resonators includes a greater impurity concentration than the at least one of the plurality of series bulk acoustic wave resonators.

In some embodiments, the at least one of the plurality of shunt bulk acoustic wave resonators includes a lower impurity concentration than the at least one of the plurality of series bulk acoustic wave resonators.

In some embodiments, each of the plurality of shunt bulk acoustic wave resonators includes substantially the same impurity concentration.

In some embodiments, each of the plurality of series bulk acoustic wave resonators includes substantially the same impurity concentration.

In some embodiments, different ones of the plurality of series bulk acoustic wave resonators include different impurity concentrations.

In some embodiments, different ones of the plurality of shunt bulk acoustic wave resonators include different impurity concentrations.

In some embodiments, each of the plurality of series bulk acoustic wave resonators include substantially the same impurity concentration.

In some embodiments, different ones of the plurality of series bulk acoustic wave resonators include different impurity concentrations.

In some embodiments, each of the plurality of series bulk acoustic wave resonators includes substantially the same impurity concentration.

In some embodiments, different ones of the plurality of series bulk acoustic wave resonators include different impurity concentrations.

In some embodiments, different ones of the plurality of series bulk acoustic wave resonators and the plurality of shunt bulk acoustic wave resonators exhibit at least three different impurity concentrations.

In some embodiments, the impurity is scandium.

In some embodiments, at least one of the plurality of shunt bulk acoustic wave or at least one of the plurality of series bulk acoustic wave resonators is one of a film bulk acoustic wave resonator, a solidly mounted resonator, or a Lamb wave resonator.

In some embodiments, the radio frequency filter is included in a radio frequency module.

In some embodiments, the radio frequency module is included in a radio frequency device.

In accordance with another aspect, there is provided a die including a plurality of acoustic wave resonators, each of the plurality of bulk acoustic wave resonators including a piezoelectric material film, the plurality of bulk acoustic wave resonators including a first subset with a first piezoelectric material film configuration causing the first subset to exhibit a relatively high kₜ² value and a second subset with a second piezoelectric material film configuration causing the second subset to exhibit a relatively lower kₜ² value than the first subset.

In some embodiments, the first piezoelectric material film configuration includes a piezoelectric material film stack including one or more of a greater thickness, a greater number of layers, or a greater dopant concentration than piezoelectric material film stack forming the second piezoelectric material film configuration.

In some embodiments, the first piezoelectric material film configuration has a first single layer piezoelectric material film stack and the second piezoelectric material film configuration has a second single layer piezoelectric material film stack, the first single layer piezoelectric material film stack having a different thickness and/or different dopant concentration than the thickness and/or dopant concentration of the second single layer piezoelectric material film stack.

In some embodiments, the plurality of bulk acoustic wave resonators form a first radio frequency filter and a second radio frequency filter, the first radio frequency filter and the second radio frequency filter having non-overlapping passbands.

In some embodiments, the first radio frequency filter and the second radio frequency filter form a duplexer.

In some embodiments, the first radio frequency filter and the second radio frequency filter are configured as ladder filters, each including series arm resonators and shunt arm resonators selected from among the plurality of bulk acoustic wave resonators.

In some embodiments, the shunt arm resonators of each of the first radio frequency filter and the second radio frequency filter exhibit substantially similar kₜ² values.

In some embodiments, the series arm resonators of each of the first radio frequency filter and the second radio frequency filter exhibit substantially similar kₜ² values.

In some embodiments, the shunt arm resonators of the first radio frequency filter and the second radio frequency filter exhibit different kₜ² values.

In some embodiments, the series arm resonators of the first radio frequency filter and the second radio frequency filter exhibit different kₜ² values.

In some embodiments, the series arm resonators of one of the first radio frequency filter or the second radio frequency filter exhibit substantially similar kₜ² values as the shunt arm resonators of the one of the first radio frequency filter or the second radio frequency filter.

In some embodiments, the series arm resonators of one of the first radio frequency filter or the second radio frequency filter exhibit different kₜ² values then the shunt arm resonators of the one of the first radio frequency filter or the second radio frequency filter.

In some embodiments, the plurality of bulk acoustic wave resonators include resonators which form parts of at least three different radio frequency filters including resonators exhibiting different kₜ² values.

In some embodiments, the die is included in an electronic device module.

In some embodiments, the electronic device module is included in a radio frequency device.

In accordance with another aspect, there is provided a method of forming a radio frequency filter. The method comprises forming a plurality of bulk acoustic wave resonators on a single die, each of the plurality of bulk acoustic wave resonators including a piezoelectric material film, the plurality of bulk acoustic wave resonators including a first subset with a first piezoelectric material film configuration causing the first subset to exhibit a relatively high kₜ² value and a second subset with a second piezoelectric material film configuration causing the second subset to exhibit a relatively lower kₜ² value than the first subset.

In some embodiments, the method comprises forming the first piezoelectric material film configuration with a piezoelectric material film stack including one or more of a greater thickness, a greater number of layers, or a greater dopant concentration than piezoelectric material film stack forming the second piezoelectric material film configuration.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of Lamb wave resonator;

FIG. 3 is a cross-sectional view of an example of a surface mounted resonator;

FIG. 4 illustrates an example of a radio frequency filter;

FIG. 5 illustrates a piezoelectric material layer for a BAW resonator including two sublayers, each having a different dopant concentration;

FIG. 6A illustrates a piezoelectric material layer for a BAW resonator including two regions with different thicknesses which exhibit different electromechanical coupling coefficient (kₜ²) values;

FIG. 6B illustrates a piezoelectric material layer for a BAW resonator including two sublayers, each having a different dopant concentration as well as two regions with different thicknesses which may be utilized to form different resonators that exhibit different electromechanical coupling coefficient (kₜ²) values;

FIG. 6C illustrates a step in a method that may be used to form the piezoelectric material layer of FIG. 6A;

FIG. 6D illustrates a step in a method that may be used to form the piezoelectric material layer stack of FIG. 6B;

FIG. 6E illustrates a step of forming a piezoelectric material layer stack in which the lower piezoelectric material layer is thinned;

FIG. 6F illustrates a step involving deposition of an upper piezoelectric material layer on the structure resulting from the step of FIG. 6E to form the piezoelectric material layer stack with regions having different thicknesses that may be used to form BAW resonators with different kₜ² values;

FIG. 7A illustrates a step in an additive method that may be used to form a piezoelectric material layer for a BAW resonator with regions having different thicknesses and kₜ² values;

FIG. 7B illustrates another step in an additive method that may be used to form a piezoelectric material layer for a BAW resonator with regions having different thicknesses and kₜ² values;

FIG. 7C illustrates another step in an additive method that may be used to form a piezoelectric material layer for a BAW resonator with regions having different thicknesses and kₜ² values;

FIG. 7D illustrates another step in an additive method that may be used to form a piezoelectric material layer for a BAW resonator with regions having different thicknesses and kₜ² values;

FIG. 7E illustrates another step in an additive method that may be used to form a piezoelectric material layer for a BAW resonator with regions having different thicknesses and kₜ² values;

FIG. 8A illustrates a step in a method of forming a piezoelectric material layer having a first portion formed of a stack of two layers of piezoelectric material and a second portion formed of a single layer of piezoelectric material;

FIG. 8B illustrates another step in the method of forming the piezoelectric material layer having the first portion formed of the stack of two layers of piezoelectric material and the second portion formed of the single layer of piezoelectric material;

FIG. 8C illustrates another step in the method of forming the piezoelectric material layer having the first portion formed of the stack of two layers of piezoelectric material and the second portion formed of the single layer of piezoelectric material;

FIG. 8D illustrates another step in the method of forming the piezoelectric material layer having the first portion formed of the stack of two layers of piezoelectric material and the second portion formed of the single layer of piezoelectric material;

FIG. 8E illustrates another step in the method of forming the piezoelectric material layer having the first portion formed of the stack of two layers of piezoelectric material and the second portion formed of the single layer of piezoelectric material;

FIG. 8F illustrates an alternative step in the method of forming the piezoelectric material layer having the first portion formed of the stack of two layers of piezoelectric material and the second portion formed of the single layer of piezoelectric material;

FIG. 8G illustrates another alternative step in the method of forming the piezoelectric material layer having the first portion formed of the stack of two layers of piezoelectric material and the second portion formed of the single layer of piezoelectric material;

FIG. 8H illustrates another alternative step in the method of forming the piezoelectric material layer having the first portion formed of the stack of two layers of piezoelectric material and the second portion formed of the single layer of piezoelectric material;

FIG. 9A illustrates a step in a method of forming different single layers of piezoelectric material in different regions of a die or wafer;

FIG. 9B illustrates another step in the method of forming different single layers of piezoelectric material in different regions of a die or wafer;

FIG. 9C illustrates another step in the method of forming different single layers of piezoelectric material in different regions of a die or wafer;

FIG. 9D illustrates another step in the method of forming different single layers of piezoelectric material in different regions of a die or wafer;

FIG. 9E illustrates another step in the method of forming different single layers of piezoelectric material in different regions of a die or wafer;

FIG. 9F illustrates another step in the method of forming different single layers of piezoelectric material in different regions of a die or wafer;

FIG. 9G illustrates another step in the method of forming different single layers of piezoelectric material in different regions of a die or wafer;

FIG. 10 schematically illustrates a single die including multiple resonators with different kₜ² values;

FIGS. 11A-11C illustrate results of a simulation of insertion loss for two different filters including resonators with piezoelectric material layers exhibiting either the same of different kₜ² values;

FIG. 11D illustrates a comparison between the transmission port contour size of the simulated filters used to obtain the insertion loss results of FIGS. 11A-11C.

FIG. 12A illustrate results of a simulation of insertion loss for another two different filters including resonators with piezoelectric material layers exhibiting either the same of different kₜ² values;

FIG. 12B illustrates a comparison between the transmission port contour size of the simulated filters used to obtain the insertion loss results of FIG. 12A.

FIG. 13 illustrates an embodiment of an electronics module;

FIG. 14 illustrates an example of a front-end module which may be used in an electronic device; and

FIG. 15 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

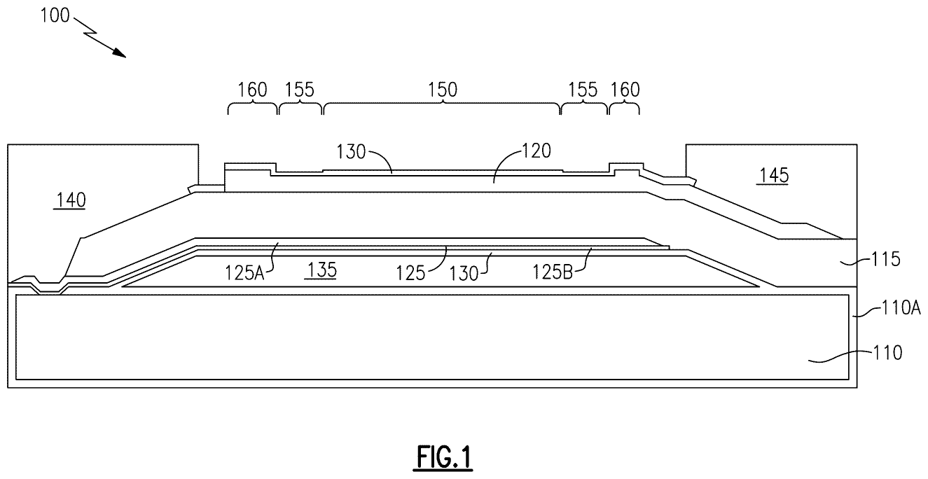

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

Another form of BAW resonator is a Lamb wave acoustic wave resonator. A Lamb wave resonator can combine features of a surface acoustic wave (SAW) resonator and a BAW resonator. A Lamb wave resonator typically includes an interdigital transducer (IDT) electrode similar to a SAW resonator. Accordingly, the frequency of the Lamb wave resonator can be lithographically defined. A Lamb wave resonator can achieve a relatively high quality factor (Q) and a relatively high phase velocity like a BAW resonator (e.g., due to a suspended structure). A Lamb wave resonator that includes an AlN or scandium-doped aluminum nitride piezoelectric layer can be relatively easy to integrate with other circuits, for example, because AlN process technology can be compatible with complementary metal oxide semiconductor (CMOS) process technology. AlN and AlScN Lamb wave resonators can overcome a relatively low resonance frequency limitation and integration challenge associated with SAW resonators and also overcome multiple frequency capability challenges associated with BAW resonators. Some Lamb wave resonator topologies are based on acoustic reflection from periodic reflective gratings. Some other Lamb wave resonator topologies are based on acoustic reflection from suspended free edges of a piezoelectric layer.

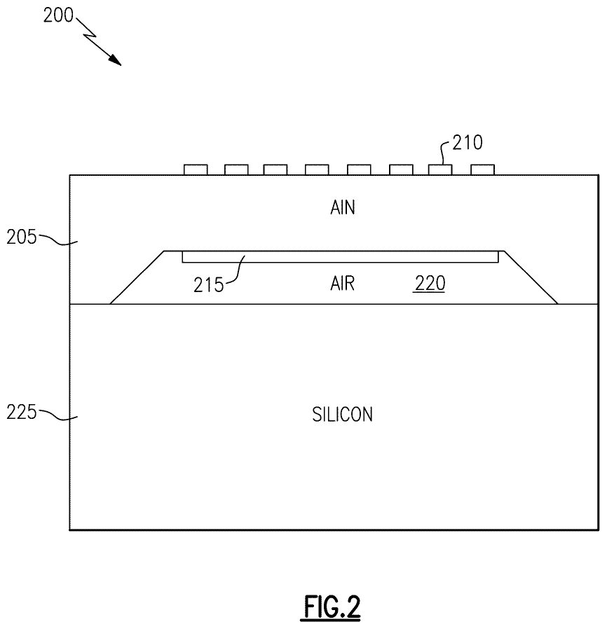

An example of a Lamb wave acoustic wave resonator is indicated generally at 200 in FIG. 2. The Lamb wave resonator 200 includes features of a SAW resonator and a film bulk acoustic wave resonator. As illustrated, the Lamb wave resonator 200 includes a piezoelectric layer 205, an interdigital transducer electrode (IDT) 210 on the piezoelectric layer 205, and a lower electrode 215 disposed on a lower surface of the piezoelectric layer 205. The piezoelectric layer 205 can be a thin film. The piezoelectric layer 205 can be an aluminum nitride or scandium-doped aluminum nitride layer. In other instances, the piezoelectric layer 205 can be any suitable piezoelectric layer. The frequency of the Lamb wave resonator can be based on the geometry of the IDT 210. The electrode 215 can be grounded in certain instances. In some other instances, the electrode 215 can be floating. An air cavity 220 is disposed between the electrode 215 and a semiconductor substrate 225. Any suitable cavity can be implemented in place of the air cavity 220, for example, a vacuum cavity or a cavity filled with a different gas.

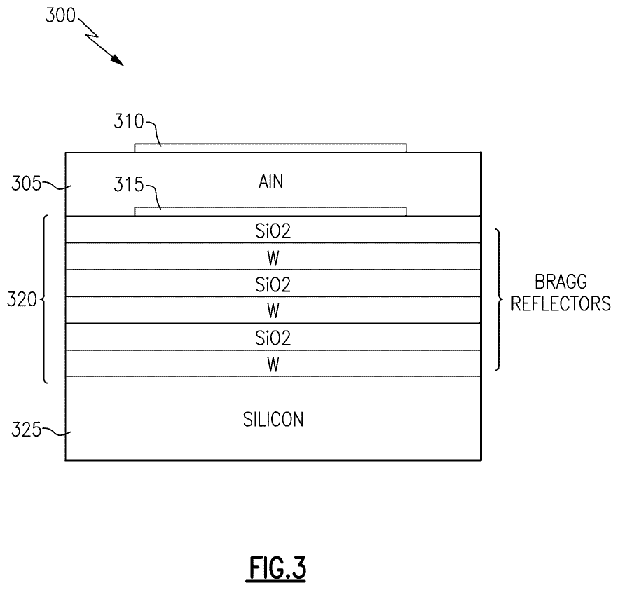

Another form of BAW resonator is a surface mounted resonator (SMR). An example of an SMR is illustrated generally at 300 in FIG. 3. As illustrated, the SMR 300 includes a piezoelectric layer 305, an upper electrode 310 on the piezoelectric layer 305, and a lower electrode 315 on a lower surface of the piezoelectric layer 305. The piezoelectric layer 305 can be an aluminum nitride or scandium-doped aluminum nitride layer. In other instances, the piezoelectric layer 305 can be any other suitable piezoelectric layer. The lower electrode 315 can be grounded in certain instances. In some other instances, the lower electrode 315 can be floating. Bragg reflectors 320 are disposed between the lower electrode 315 and a semiconductor substrate 325. The semiconductor substrate 325 can be a silicon substrate. Any suitable Bragg reflectors can be implemented. For example, the Bragg reflectors can be SiO₂/W.

It should be appreciated that the BAW resonators and piezoelectric film illustrated in the figures are illustrated in a highly simplified form. The relative dimensions of the different features are not shown to scale. Further, typical BAW resonators may include additional features or layers not illustrated.

In some embodiments, multiple BAW resonators as disclosed herein may be combined into a filter, for example, an RF ladder filter schematically illustrated in FIG. 4 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

One parameter that affects the performance of a BAW resonator is electromechanical coupling coefficient, typically given the symbol kₜ². One method by which the kₜ² of different BAW resonators may be controlled is by selecting the mass loading applied to the BAW resonator. This may be accomplished by selecting the thickness of the upper and/or lower electrode of the BAW resonator. Different BAW resonators on a die may exhibit different kₜ² values even if they have the same piezoelectric material layer or stack thickness if they have electrodes with different thicknesses and thus different mass loadings. Whether the kₜ² value of a BAW resonator increases or decreases with increased electrode mass loading depends on the structure of the piezoelectric material layer or stack. The kₜ² value might increase due to stronger confinement of energy in the piezoelectric layer or decrease due to increased stack asymmetry.

Another method by which the kₜ² of a BAW resonator may be controlled is by trimming the piezoelectric material layer, for example, by bombarding the surface of the piezoelectric material layer with argon ions, or by etching the piezoelectric material layer by, for example, reactive ion etching (RIE).

A further method by which the kₜ² of a BAW resonator may be controlled is by doping the piezoelectric material with a dopant such as scandium (Sc). A greater concentration of Sc in the piezoelectric material layer of a BAW resonator will generally increase the kₜ² of the resonator (often at the expense of degrading the quality factor of the resonator), at least until one reaches a Sc concentration of 40%-45% at which point the crystal structure of the piezoelectric material layer may be degraded and the piezoelectric effect may suffer.

In conventional processes, the piezoelectric material layers of all resonators on a die or on an entire wafer are subjected to the same treatment process for adjusting kₜ². If one wanted to change the effective kₜ² of one or more of the resonators in a ladder filter, for example, any of R1-R9 in the ladder filter of FIG. 3, to change operating characteristics of the filter one could split the resonator into 2 or more resonators operating in parallel and/or add a capacitor in parallel to the resonator. These methods of changing the effective kₜ² are not generally optimal because they will typically increase the footprint of the die on which the filter is implemented, reducing the number of die that could be formed on a single wafer and decreasing die yield.

It has been discovered that one may achieve the beneficial effects of providing different resonators in a filter with different kₜ² parameter values without the negative effect of increasing die size in accordance with conventional methods by performing different treatments on different resonators so that different resonators exhibit different kₜ² parameter values. One may, for example, trim, etch, or dope the piezoelectric material layers of one or more shunt resonators in a ladder filter differently than one or more of the series resonators. These methods may allow one to change the kₜ² parameter values of different resonators to a greater extent than could be achieved by utilizing different electrode thicknesses on the different resonators to give them different mass loadings.

The ability to select different kₜ² parameter values for different resonators on a single die may provide for one to fabricate multiple filters having different performance parameters or passbands on a single die, leading to an overall reduction in die size for a device. Two filters on the same die may include resonators with different piezoelectric layer/stack thicknesses. The filters would potentially share some of the other layer thicknesses, for example, electrodes, passivation layers, and mass loads. These filters can be Tx/Rx filters of the same band, Tx/Rx filters of different bands, two Tx filters of different bands or two Rx filters of different bands. The advantage of doing this is die size reduction, because both filters can share certain ports, for example, antenna and ground ports and the total die edge length is reduced.

BAW filters are typically manufactured as single filters and then assembled with surface mount technology components on a laminate. It is challenging to design the optimal component layout for matching and to minimize parasitics. Increasing the filter density, as is enabled by aspects and embodiments disclosed herein, ensures that more filters are at the optimal location.

In some embodiments each of the shunt resonators in a ladder filter may exhibit the same kₜ² parameter value and each of the series resonators may exhibit the same kₜ² parameter value that is different from the kₜ² parameter value of each of the shunt resonators. The terms “the same,” “substantially the same,” and “substantially similar” and grammatical variations as used herein when referencing various parameter values, dopant concentrations, dimensions, etc. should be understood to mean the same subject to differences that may result from manufacturing variability, age, etc. Further, the term “substantially the same kₜ² parameter value,” “substantially similar kₜ² parameter values” or grammatical variations as used herein should be understood to mean kₜ² parameter values that result from the same intended film stacks but subject to variation due to the thickness of other layers in the stack (electrodes, mass loads, passivation thicknesses, etc.). In other embodiments, different processing methods applied to the different resonators may result in different resonators with 3 or more different respective kₜ² parameter values.

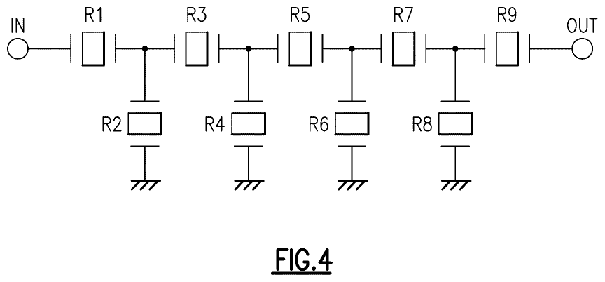

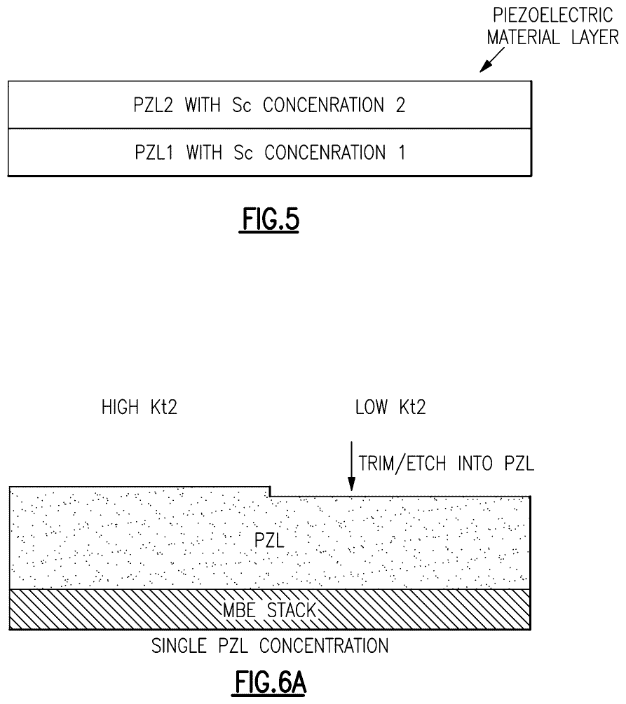

In combination with methods and configurations disclosed herein that provide different resonators in a filter with different kₜ² parameter values, the piezoelectric material layers utilized in BAW resonators as disclosed herein may include different sub-layers with different Sc concentrations to tune the kₜ² parameter values of the resonators. As illustrated schematically in FIG. 5 a piezoelectric material layer of any of the forms of BAW resonators disclosed herein may include a lower sub-layer PZL1 with a first concentration of Sc and an upper sub-layer with a second concentration of Sc. Either of the first or second concentrations of Sc may range from 0 atomic % to 40 atomic %. Either of the first or second concentrations of Sc may be higher or lower than the other of the first or second concentrations of Sc. Piezoelectric material layers including lower and upper sub-layers may be referred to as piezoelectric material layer stacks. The term “piezoelectric material layer stack” as used herein may refer to a multi-layer stack of piezoelectric material or a single layer of piezoelectric material.

Several methods by which piezoelectric material layers for BAW resonators with different kₜ² parameter values may be fabricated are now illustrated. These methods fall generally into two categories:
A) Subtractive methods, where the whole piezoelectric material stack is deposited first and then the portion intended to be used to form a resonator that exhibits a relatively lower kₜ² value than resonators formed using other portions of the piezoelectric material stack is trimmed/etched to the desired thickness and kₜ²; or
B) Additive method, where first portions of the piezoelectric material layer intended to be used to form a resonator that exhibits a relatively lower kₜ² value than resonators formed using other portions of the piezoelectric material stack never is trimmed/etched. It is protected by a hard mask (HM), whose removal does not negatively impact the piezoelectric material layer. Other regions of the piezoelectric material layer intended to be used to form a resonator that exhibits a relatively higher kₜ² than the first portions are then grown thicker than the first portions. The additive methodologies may be preferred where a greater difference in resonator kₜ² values is desired in different portions of a die, e.g., for different resonators in a filter.

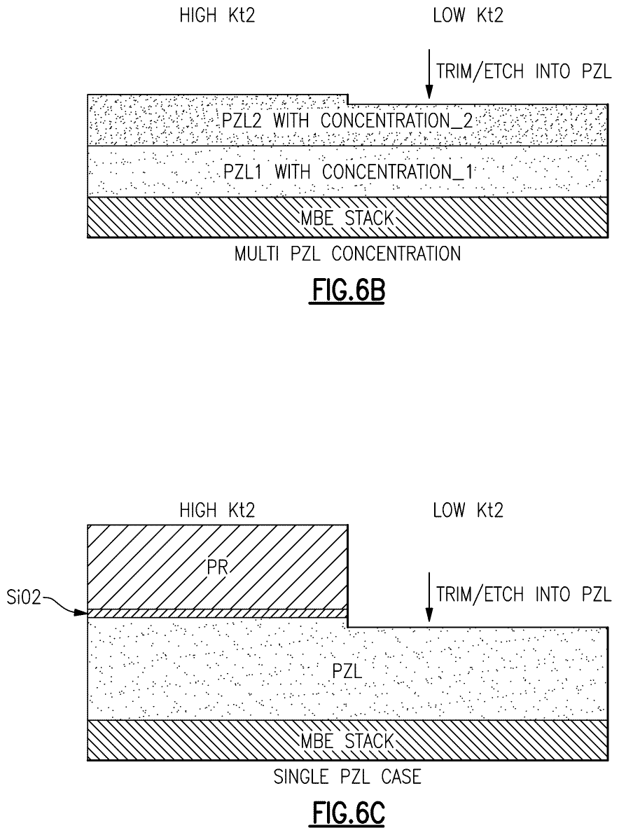

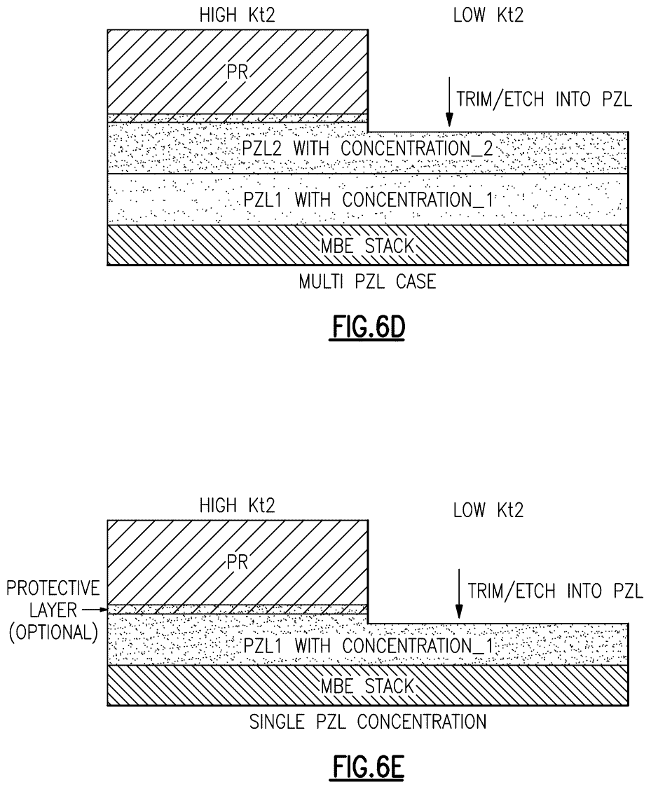

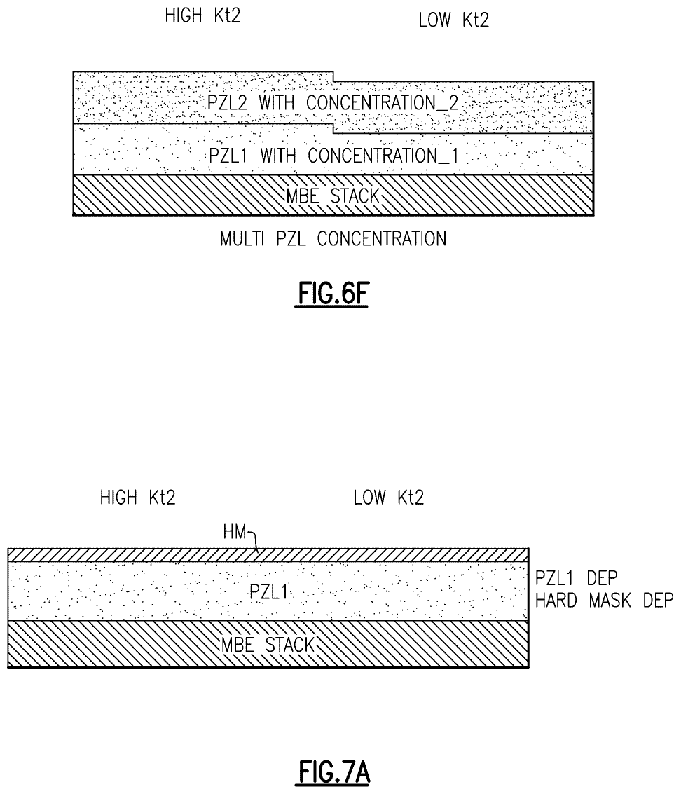

FIG. 6A illustrates one example of a subtractive method. In this example, a piezoelectric material layer PZL having a constant impurity (e.g., Sc) concentration is grown on a bottom electrode (MBE). A portion of the PZL intended to be used to form a resonator that exhibits a lower kₜ² is etched/trimmed to a desired thickness to achieve the desired kₜ². A similar process may be performed where the piezoelectric material layer includes two sublayers with different impurity (e.g., Sc) concentrations in which the upper sublayer may be trimmed/etched to form a portion with a reduced kₜ² as shown in FIG. 6B. In some embodiments, illustrated schematically in FIGS. 6C and 6D, a layer of SiO₂ (optional) and a layer of photoresist (PR) may be first deposited before trimming/etching to protect the portions of the piezoelectric material layer that one does not intend to thin. The photoresist and optional SiO₂ layer may be removed after etching/trimming the desired portion of the piezoelectric material layer using processes known in the art. In another embodiment, illustrated schematically in FIGS. 6E and 6F, the lower piezoelectric material layer is thinned to form a portion that may be used to form a resonator with a reduced kₜ². As illustrated in FIG. 6E, a portion of a lower piezoelectric material layer of a piezoelectric material stack which will be used to form a resonator with a higher kₜ² is masked with photoresist and an optional protective layer (e.g., SiO₂) and the unmasked portion of the lower piezoelectric material layer is thinned by etching or trimming. The photoresist and protective layer is then removed and an upper piezoelectric material layer with different dopant (e.g., Sc) concentration than the lower piezoelectric material layer is conformally deposited on the lower piezoelectric material layer to form a piezoelectric material layer stack with portions from which resonators having higher and lower kₜ² parameter values may be formed. The thinner portion of the piezoelectric material stack could be used to form a BAW resonator with a lower kₜ² parameter value and the thicker portion of the piezoelectric material layer stack could be used to form a BAW resonator with a relatively higher kₜ² parameter value.

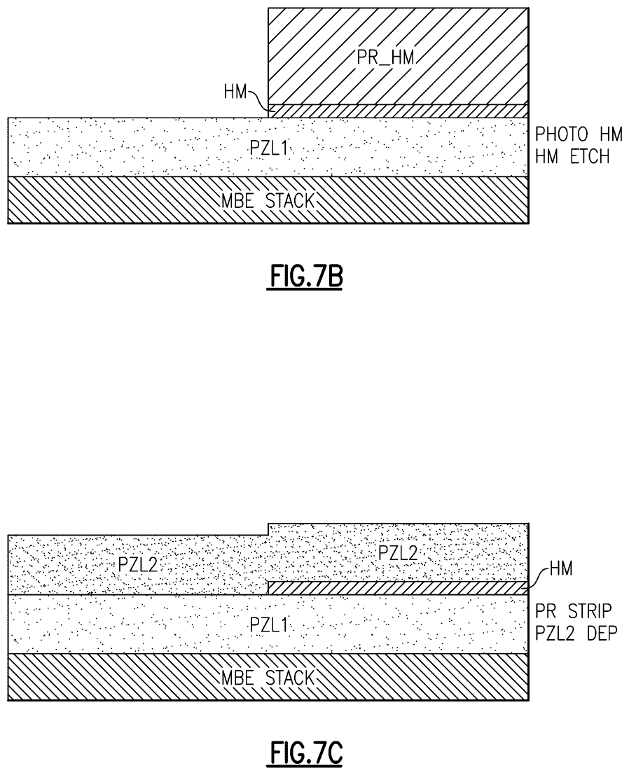

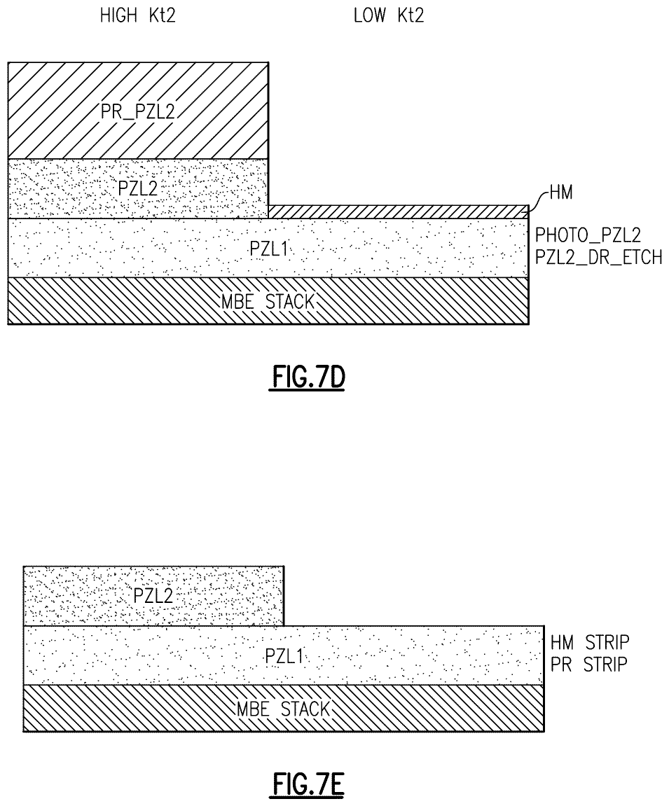

Another example of a method of forming a piezoelectric material layer stack with different portions that may be utilized to form BAW resonators having different kₜ² parameter values is illustrated in FIGS. 7A-7E. This method may result in a piezoelectric material layer stack with different portions that may be utilized to form BAW resonators having kₜ² parameter values that exhibit a greater difference than the methods of FIGS. 6A-6F. As shown in FIG. 7A after forming a layer of piezoelectric material on a bottom electrode, a hard mask (formed of e.g., W, Mo, SiO₂ or another appropriate material) is deposited on top of the layer of piezoelectric material. A layer of photoresist (PR_HM) is deposited over a portion of the hard mask that is to remain and cover the portion of the layer of piezoelectric material that is not to be thickened and the exposed portion of the hard mask is then etched. (FIG. 7B.)

The photoresist covering the hard mask is removed and a layer of additional piezoelectric material (PZL2) is deposited. A first portion of the additional piezoelectric material is deposited on the exposed upper surface of the original piezoelectric material layer and a second portion of the additional piezoelectric material is deposited on the upper surface of the hard mask. (FIG. 7C.)

A layer of photoresist (PR_PZL2) is then deposited and patterned on the upper surface of the layer of additional piezoelectric material that is intended to remain and form the thickened, high kₜ² portion of the piezoelectric material layer. The portion of the layer of additional piezoelectric material PZL2 not protected by the photoresist PR_PZL2 is then removed, e.g., by dry etching. (FIG. 7D.)

The photoresist PR_PZL2 and hard mask are then removed by dry or wet etching, leaving the piezoelectric material layer with a thicker region including piezoelectric material sublayers PZL1 and PZL2 and a thinner region including only piezoelectric material sublayer PLZ1. (FIG. 7E.) The thicker region of the piezoelectric material layer will exhibit a higher kₜ² value than the thinner region of the piezoelectric material layer.

In variations of the method illustrated in FIGS. 7A-7E, one or both of the piezoelectric material layers PZL1, PZL2 may be formed on 2 or more sub-layers, optionally with different dopant (e.g., Sc) concentrations. This method may be combined with other methods of adjusting the kₜ² values of resonators to be formed in the different regions, for example, by forming the PZL1 and PZL2 layers with different concentrations of dopant (e.g., Sc) or by forming the PZL1 layer in the different regions with different concentrations of dopant (e.g., Sc).

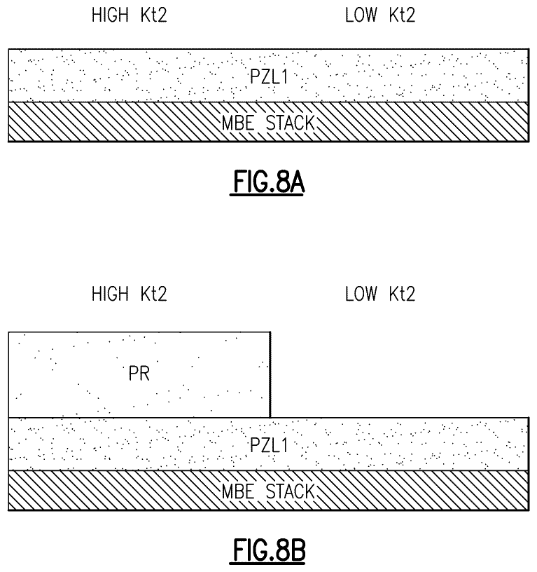

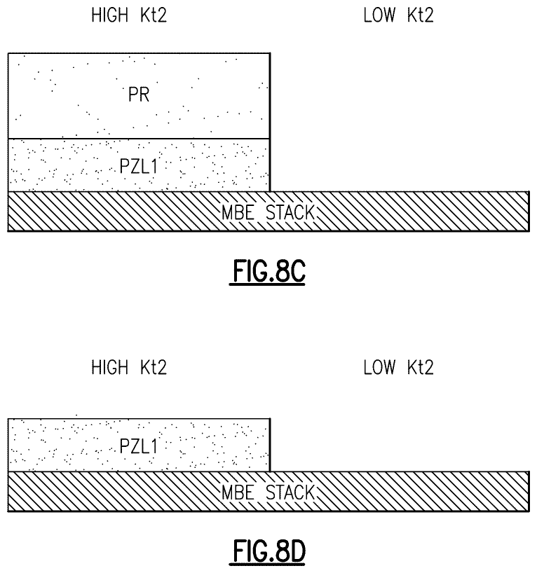

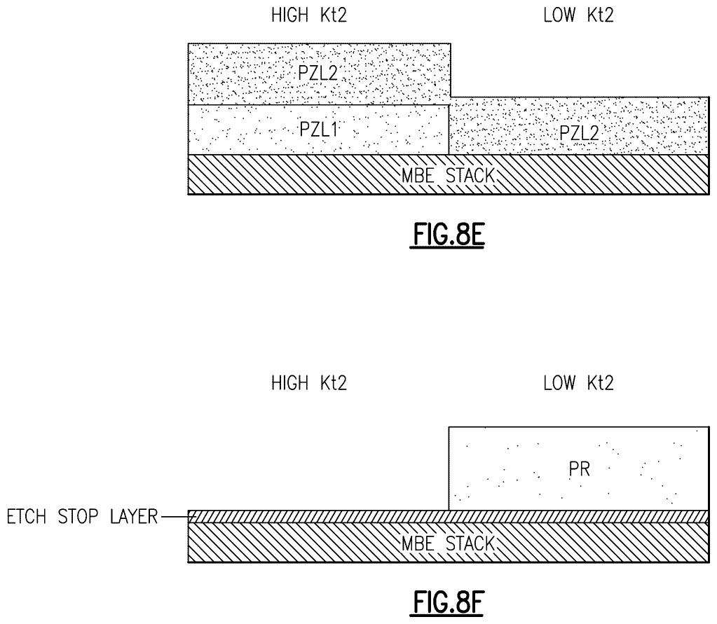

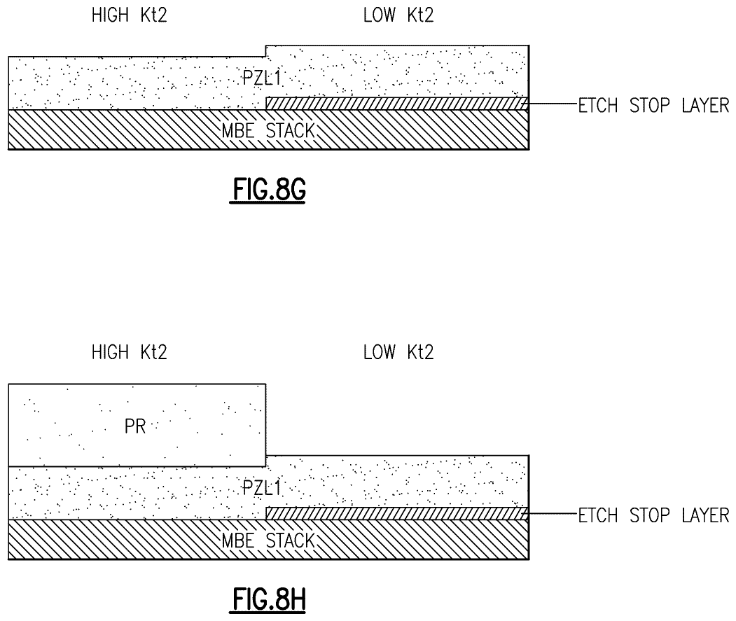

FIGS. 8A-8E illustrate a method of forming a piezoelectric material layer having a first portion formed of a stack of two layers of piezoelectric material and a second portion formed of a single layer of piezoelectric material. The single layer of piezoelectric material in the second portion may extend into the first portion to form the upper piezoelectric material layer of the piezoelectric material layer stack and may have the same thickness in the first and second portions. FIG. 8A illustrates a piezoelectric material layer PZL1 deposited on a bottom electrode stack (MBE Stack). FIG. 8B illustrates that a layer of photoresist is deposited over a region of the PZL1 layer where a resonator exhibiting a relatively higher kₜ² value is to be formed while a region in which a resonator exhibiting a relatively lower kₜ² value is to be formed is left exposed. FIG. 8C illustrates that the PLZ1 layer is etched away in the region in which the resonator exhibiting the relatively lower kₜ² value is to be formed. The selectivity of the etching of the PZL1 layer over the MBE Stack is sufficiently high that the MBE Stack may not need an etch stop layer. The photoresist layer is then removed (FIG. 8D) and a second piezoelectric material layer PZL2 is deposited on the structure resulting in the structure shown in FIG. 8E. The PZL2 layer is disposed on top of the PZL1 layer in the region in which the resonator exhibiting the relatively higher kₜ² value is to be formed and is disposed directly on the MBE stack in the region in which the resonator exhibiting the relatively lower kₜ² value is to be formed. The PZL1 and PZL2 layers may have the same or different thicknesses. The PZL1 and PZL2 layers may have the same or different dopant (e.g., Sc) concentrations.

In a variation of the method shown in FIGS. 8A-8E, the selectivity of the etch of the PZL1 layer over the MBE Stack may not be sufficiently high such that the PZL1 layer may be etched from the MBE Stack without damaging the MBE Stack. In this variation an etch stop layer (e.g., SiO₂) is deposited and patterned to protect the MBE Stack during the PZL1 layer etch. FIG. 8F illustrates that an etch stop layer may be deposited on the MBE Stack. A layer of photoresist is deposited on the etch stop layer in the region in which the resonator exhibiting the relatively lower kₜ² value is to be formed. An etchant that is selective to the etch stop layer relative to the MBE Stack is used to remove the etch stop layer from the region in which the resonator exhibiting the relatively higher kₜ² value is to be formed. The photoresist is then removed and a first piezoelectric material layer PZL1 is deposited on the exposed portion of the MBE Stack and the remaining portion of the etch stop layer. (FIG. 8G.) Another photoresist layer is deposited on the PZL1 layer in the region in which the resonator exhibiting the relatively higher kₜ² value is to be formed. (FIG. 8H.) The exposed portion of the PZL1 layer is etched with an etchant that is selective to the PZL1 layer relative to the etch stop layer and then the remaining portion of the etch stop layer is removed with an etchant that is selective to the etch stop layer relative to the MBE Stack to result in the structure shown in FIG. 8C described above.

In other embodiments, instead of forming resonators with different kₜ² values on different portions of a die or wafer by forming some of the resonators with piezoelectric material layers including multiple layers of piezoelectric material and others of the resonators with single layers of piezoelectric material, one may form resonators on different portions of the die or wafer with piezoelectric material layers having single layers but with different thicknesses and/or impurity (e.g., Sc) doping.

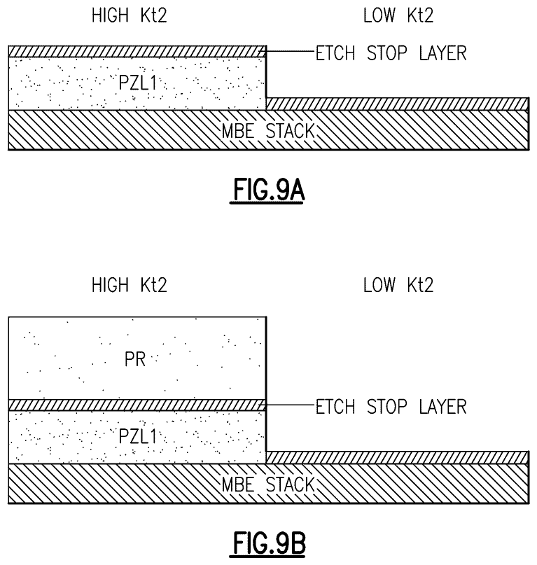

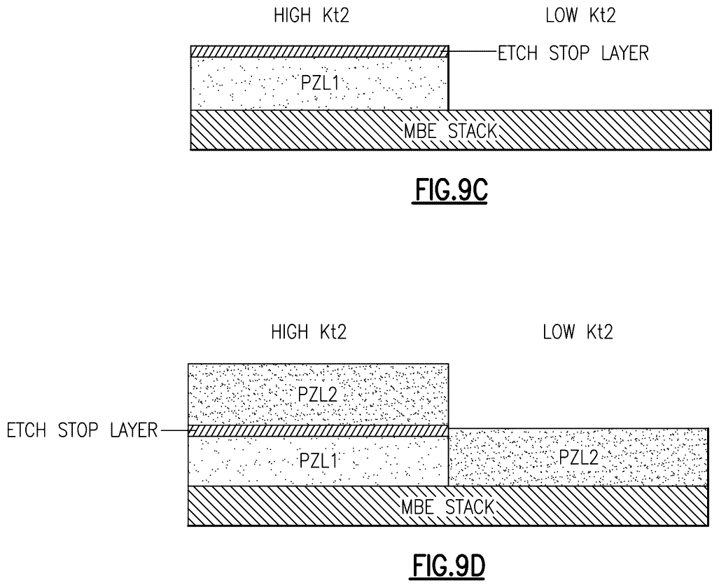

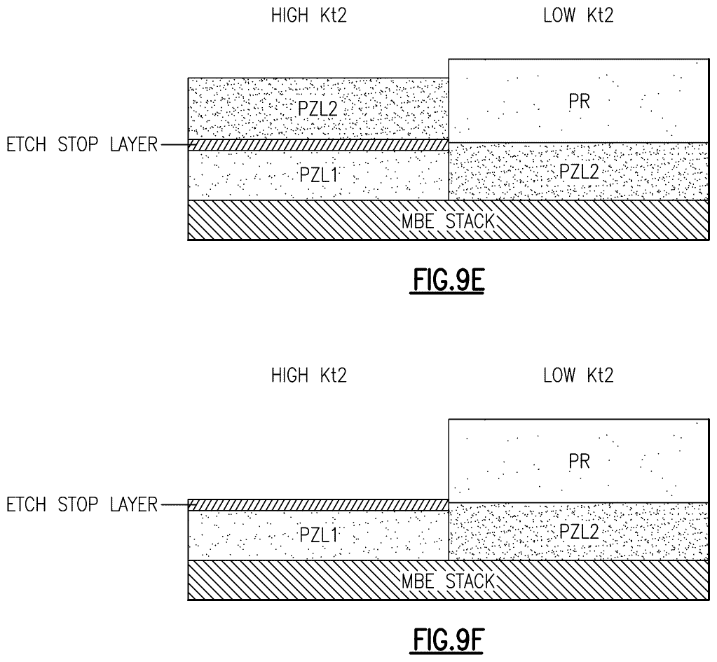

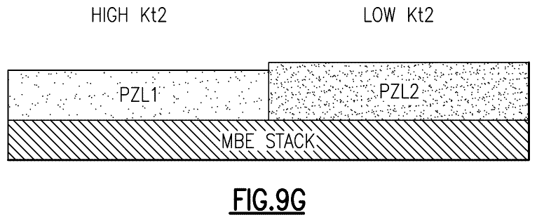

One example of a process flow for forming these different piezoelectric material layers on different portions of a die or wafer is shown in FIGS. 9A-9G. The method includes the same process flow as illustrated in FIG. 8A-8D or 8F-8H, to form the structure shown in FIG. 8D. From the structure shown in FIG. 8D, an etch stop layer is then deposited over the piezoelectric material layer PZL1 and over the exposed portion of the MBE Stack as shown in FIG. 9A. A layer of photoresist PR is deposited and patterned to cover the etch stop layer on top of the PZL1 layer and to leave the etch stop layer on the MBE Stack exposed as shown in FIG. 9B. The portion of the etch stop layer on the MBE stack is then removed, for example, by wet or dry etching, and then the layer of photoresist is removed, resulting in the structure shown in FIG. 9C. A layer of piezoelectric material PZL2 having a different thickness and/or different dopant concentration than the layer of piezoelectric material PZL1 is then deposited over the remaining portion of the etch stop layer on top of the PZL1 layer and on the exposed portion of the MBE Stack as shown in FIG. 9D. A layer of photoresist is deposited and patterned on the portion of the PZL2 layer that is not above the PZL1 layer (FIG. 9E) and the portion of the PZL2 layer that is above the PZL1 and etch stop layer is then removed, for example, by wet or dry etching (FIG. 9F). The portion of the etch stop layer on top of the PZL1 layer and the remaining photoresist are then removed to result in the structure of FIG. 9G in which the single PZL1 layer is present in some portions of the die or wafer and the single PZL2 layer is present in other portions of the die or wafer. Resonators having different kₜ² values on different portions of the die or wafer may then be formed using the single PZL1 layer or the single PZL2 layer as their piezoelectric material layers.

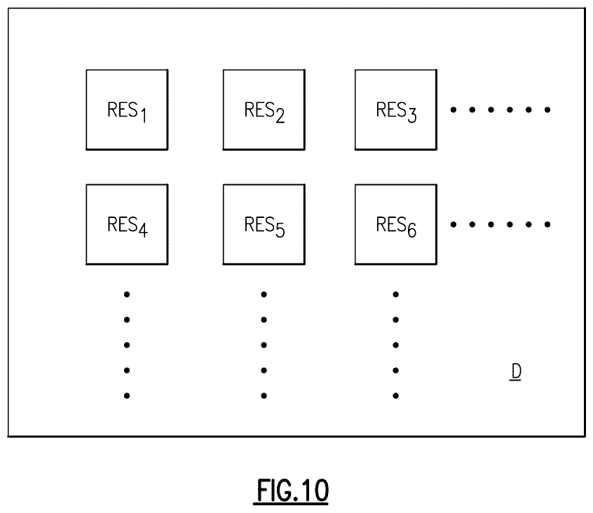

As discussed above, the formation of piezoelectric material stacks with different thicknesses, numbers of layers, or dopant concentrations on different portions of a single die may provide for different resonators having different kₜ² values to be formed on different portions of the die having piezoelectric material stacks with different properties. As shown in FIG. 10 a single die D may include multiple RAW resonators Res₁-Res₆ (although more or fewer resonators may be present). One or more of the resonators Res₁-Res₆ may have a different kₜ² value than one or more other of the resonators Res₁-Res₆. The different resonators Res₁-Res₆ may have more than two different kₜ² values. The different resonators Res₁-Res₆ may be electrically connected in one circuit to form a filter, duplexer, triplexer, or other circuit or one or more of the resonators Res₁-Res₆ may form part of a different circuit than one or more other of the resonators Res₁-Res₆.

In one example, a first filter may be formed from resonators on the die D each exhibiting relatively higher kₜ² values than other resonators of the die D each exhibiting relatively lower kₜ² values and forming a second filter. In other examples, two different ladder filters may be formed on the die D from different resonators exhibiting relatively higher kₜ² values or relatively lower kₜ² values for their respective series and shunt resonators in accordance with Table 1 below where “H” indicates resonators with relatively higher kₜ² values and “L” represents resonators with relatively lower kₜ² values.

TABLE 1
Examples of ladder filters on a single die with series
and shunt resonators exhibiting relatively higher kₜ² values
(H) or relatively lower kₜ² values (L)

| | |
|---|---|
| Filter 1 | Filter 2 |

| | Series | Shunt | Series | Shunt |
|---|---|---|---|---|
| 3H, 1L | H | H | H | L |
| | H | H | L | H |
| 3L, 1H | L | L | H | L |
| | L | L | L | H |
| 2H, 2L | H | H | L | L |
| | H | L | H | L |
| | H | L | L | H |
| | L | H | L | H |

In other examples, filter 1 and filter 2 may be combined into a duplexer, or the die D may include resonators forming more than two different filters.

### Example 1

Simulated values of insertion loss for a ladder filter including both series and shunt resonators with the same low Sc doping level (filter 1) were compared to simulated values of insertion loss of a resonator with the same topology but in which the series resonators had a higher Sc doping level and the shunt resonators had a lower Sc doping level (filter 2).

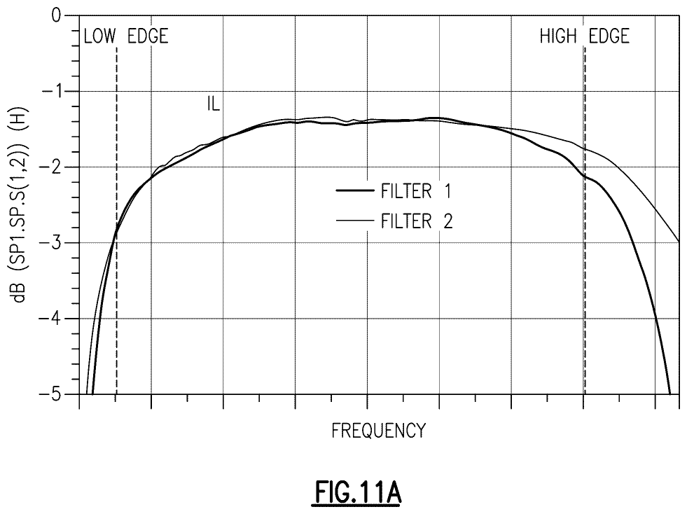

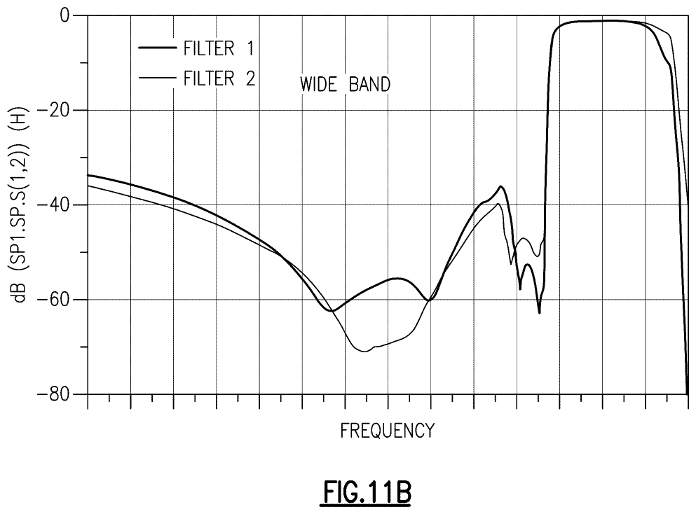

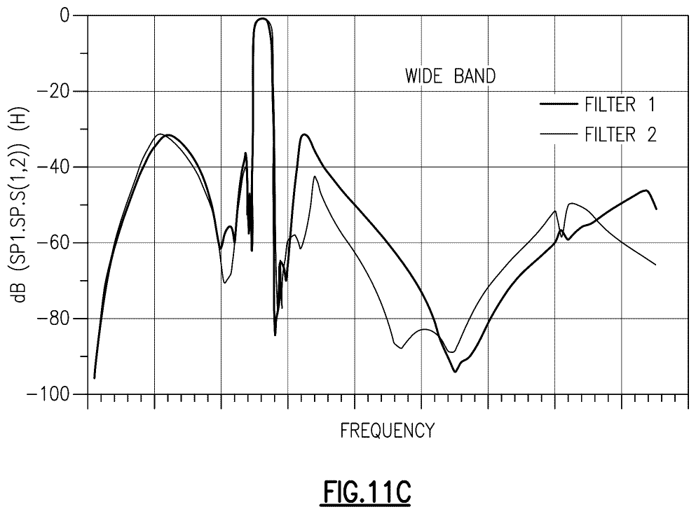

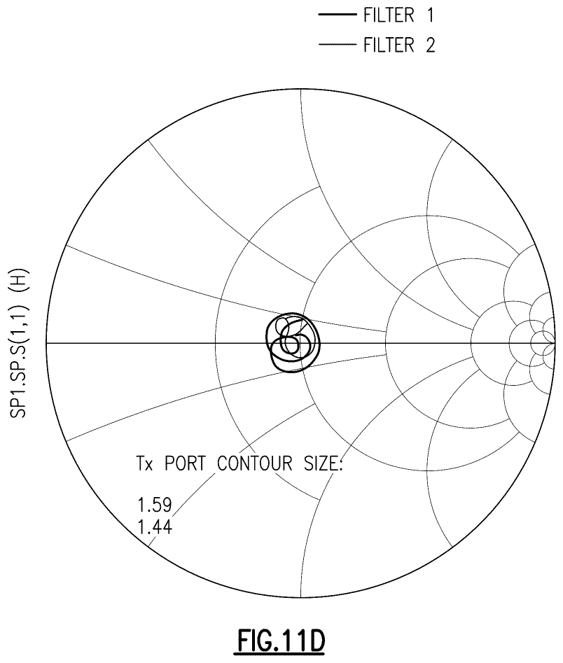

FIG. 11A illustrates a comparison of the insertion loss values for the two filters in the region of the passband of the filters. FIG. 11B shows insertion loss values over a greater decibel range and a greater frequency range on the lower side of the passband than FIG. 11A. FIG. 11C shows insertion loss values over a greater decibel range and a greater frequency range on both lower and upper sides of the passband than FIG. 11A. FIG. 11D is a Smith chart showing transmit port contour sizes for each of the filters. From FIG. 11A it can be seen that insertion loss on the high end of the filter passband was improved for filter 2 as compared to filter 1. From FIG. 11B it can be seen that rejection at frequencies below the passband was improved for filter 2 as compared to filter 1. From FIG. 11C it can be seen that insertion loss at frequencies above the passband, including at the second harmonic of the resonance frequencies of the resonators of the filter, was improved for filter 2 as compared to filter 1. From FIG. 11D it can be seen that the transmit port contour size was reduced for filter 2 as compared to filter 1 which indicates that the transmit port impedance of filter 2 would change less with frequency than that of filter 1 making it easier to match the impedance of filter 2 to components connected to it than filter 1.

### Example 2

Simulated values of insertion loss for a ladder filter including both series and shunt resonators with the same high Sc doping level (filter 3) were compared to simulated values of insertion loss of a resonator with the same topology but in which the series resonators had a higher Sc doping level and the shunt resonators had a lower Sc doping level (filter 4).

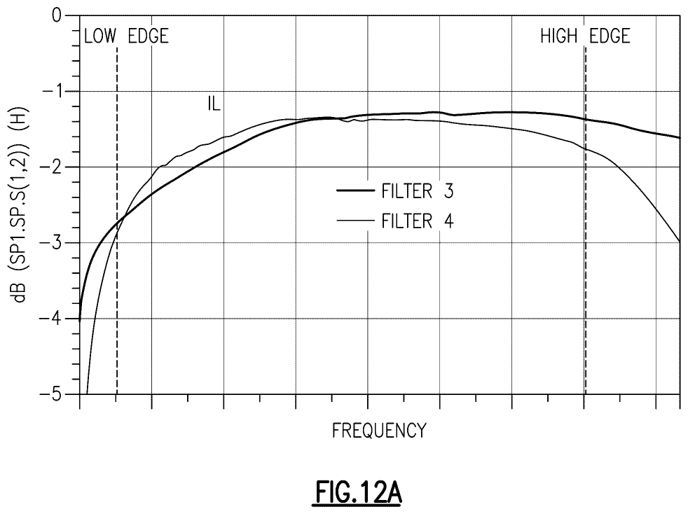

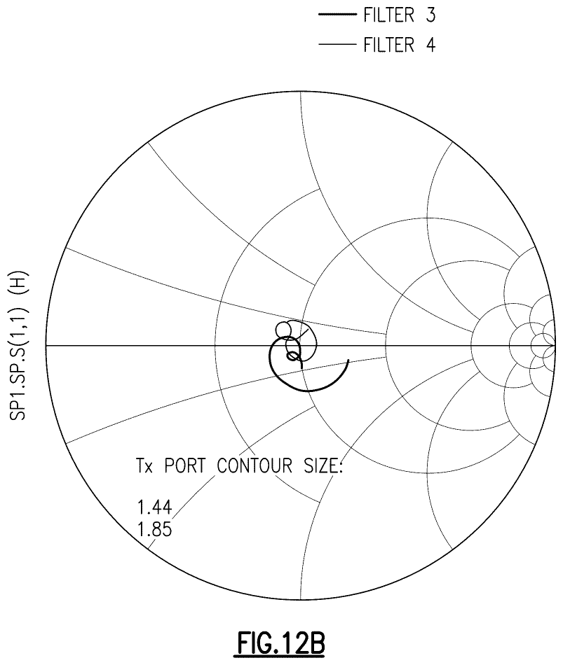

FIG. 12A illustrates a comparison of the insertion loss values for the two filters in the region of the passband of the filters. FIG. 12B is a Smith chart showing transmit port contour sizes for each of the filters. From FIG. 12A it can be seen that insertion loss is more symmetric at the low and high edges of the filter passband for filter 4 as compared to filter 3. From FIG. 12B it can be seen that the transmit port contour size was reduced for filter 4 as compared to filter 3 which indicates that the transmit port impedance of filter 4 would change less with frequency than that of filter 3 making it easier to match the impedance of filter 4 to components connected to it than filter 3.

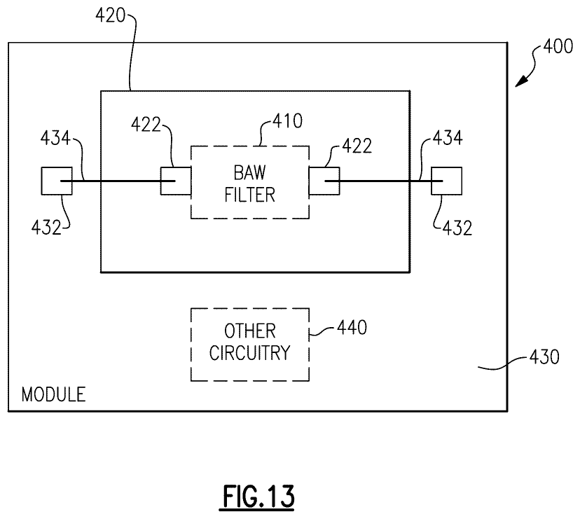

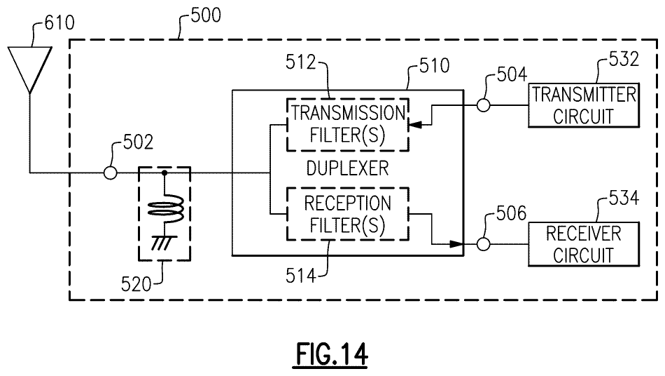

The acoustic wave devices discussed herein can be implemented in a variety of packaged modules. Some example packaged modules will now be discussed in which any suitable principles and advantages of the packaged acoustic wave devices discussed herein can be implemented. FIGS. 13, 14, and 15 are schematic block diagrams of illustrative packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example. FIG. 13 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

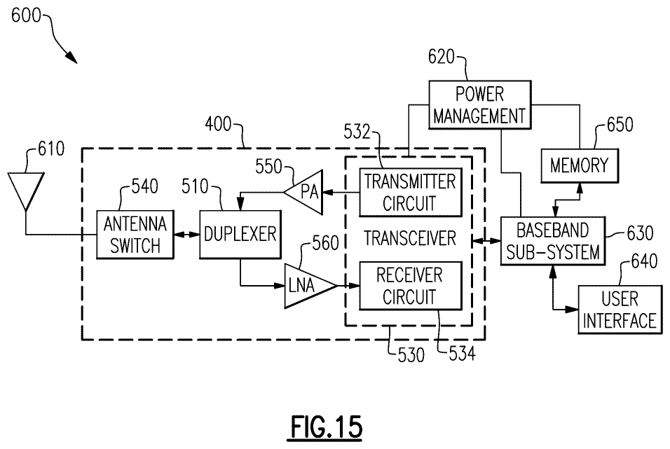

Referring to FIG. 14, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 14, however in other embodiments these components may be integrated into a common transceiver circuit or module. As will be appreciated by those skilled in the art, the front-end module 500 may include other components that are not illustrated in FIG. 14 including, but not limited to, switches, electromagnetic couplers, amplifiers, processors, and the like.

FIG. 15 is a block diagram of one example of a wireless device 600 including the antenna duplexer 510 shown in FIG. 14. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 14. The front-end module 500 includes the duplexer 510, as discussed above. In the example shown in FIG. 15 the front-end module 500 further includes an antenna switch 540, which can be configured to switch between different frequency bands or modes, such as transmit and receive modes, for example. In the example illustrated in FIG. 15, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 14.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 15, the front-end module 500 may further include a low noise amplifier module 560, which amplifies received signals from the antenna 610 and provides the amplified signals to the receiver circuit 534 of the transceiver 530.

The wireless device 600 of FIG. 15 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A radio frequency filter comprising:
a plurality of series bulk acoustic wave resonators; and
a plurality of shunt bulk acoustic wave resonators, at least one of the plurality of shunt bulk acoustic wave resonators exhibiting a different electromechanical coupling coefficient than at least one of the plurality of series bulk acoustic wave resonators, at least one of the bulk acoustic wave resonators exhibiting a higher electromechanical coupling coefficient than another one of the bulk acoustic wave resonators having a thicker piezoelectric material layer stack than the another one of the bulk acoustic wave resonators.

2. The radio frequency filter of claim 1 wherein each of the plurality of shunt bulk acoustic wave resonators exhibits substantially the same electromechanical coupling coefficient.

3. The radio frequency filter of claim 2 wherein different ones of the plurality of series bulk acoustic wave resonators exhibit different electromechanical coupling coefficients.

4. The radio frequency filter of claim 1 wherein different ones of the plurality of shunt bulk acoustic wave resonators exhibit different electromechanical coupling coefficients.

5. The radio frequency filter of claim 4 wherein different ones of the plurality of series bulk acoustic wave resonators exhibit different electromechanical coupling coefficients.

6. The radio frequency filter of claim 1 wherein different ones of the plurality of series bulk acoustic wave resonators and the plurality of shunt bulk acoustic wave resonators exhibit at least three different electromechanical coupling coefficients.

7. The radio frequency filter of claim 1 wherein at least one of the plurality of shunt bulk acoustic wave resonators includes a piezoelectric material having a different impurity concentration than at least one of the plurality of series bulk acoustic wave resonators.

8. The radio frequency filter of claim 1 wherein different ones of the plurality of series bulk acoustic wave resonators include different impurity concentrations.

9. The radio frequency filter of claim 1 wherein different ones of the plurality of shunt bulk acoustic wave resonators include different impurity concentrations.

10. The radio frequency filter of claim 1 wherein different ones of the plurality of series bulk acoustic wave resonators and the plurality of shunt bulk acoustic wave resonators exhibit at least three different impurity concentrations.

11. A radio frequency module including the radio frequency filter of claim 1.

12. A radio frequency device including the radio frequency module of claim 11.

13. A die including a plurality of acoustic wave resonators, each of the plurality of bulk acoustic wave resonators including a piezoelectric material film, the plurality of bulk acoustic wave resonators including a first subset with a first piezoelectric material film configuration causing the first subset to exhibit a relatively high kₜ² value and a second subset with a second piezoelectric material film configuration causing the second subset to exhibit a relatively lower kₜ² value than the first subset.

14. The die of claim 13 wherein the first piezoelectric material film configuration includes a piezoelectric material film stack including one or more of a greater thickness, a greater number of layers, or a greater dopant concentration than piezoelectric material film stack forming the second piezoelectric material film configuration.

15. The die of claim 14 wherein the first piezoelectric material film configuration has a first single layer piezoelectric material film stack and the second piezoelectric material film configuration has a second single layer piezoelectric material film stack, the first single layer piezoelectric material film stack having a different thickness and/or different dopant concentration than the thickness and/or dopant concentration of the second single layer piezoelectric material film stack.

16. The die of claim 13 wherein the plurality of bulk acoustic wave resonators form a first radio frequency filter and a second radio frequency filter, the first radio frequency filter and the second radio frequency filter having non-overlapping passbands.

17. The die of claim 16 wherein the first radio frequency filter and the second radio frequency filter are configured as ladder filters, each including series arm resonators and shunt arm resonators selected from among the plurality of bulk acoustic wave resonators.

18. The die of claim 17 wherein the series arm resonators of one of the first radio frequency filter or the second radio frequency filter exhibit different kₜ² values then the shunt arm resonators of the one of the first radio frequency filter or the second radio frequency filter.

19. A method of forming a radio frequency filter, the method comprising forming a plurality of bulk acoustic wave resonators on a single die, each of the plurality of bulk acoustic wave resonators including a piezoelectric material film, the plurality of bulk acoustic wave resonators including a first subset with a first piezoelectric material film configuration causing the first subset to exhibit a relatively high kₜ² value and a second subset with a second piezoelectric material film configuration causing the second subset to exhibit a relatively lower kₜ² value than the first subset.

20. The method of claim 19 further comprising forming the first piezoelectric material film configuration with a piezoelectric material film stack including one or more of a greater thickness, a greater number of layers, or a greater dopant concentration than piezoelectric material film stack forming the second piezoelectric material film configuration.
